(19) United States
(12) Patent Application Publication
(10) Pub. No.: US 2008/0157196 A1
(43) Pub. Date: Jul. 3, 2008

(54) DMOS device and method for fabricating the same

(75) Inventor: Duck Ki Jang, Bucheon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu HiTek Co., Ltd.

(21) Appl. No.: 12/003,613

(22) Filed: Dec. 28, 2007

(30) Foreign Application Priority Data
Dec. 29, 2006 (KR) 10-2006-0137345

(51) Int. Cl. H01L 27/092; H01L 21/8238

(52) U.S. Cl. 257/338; 438/217; 257/E27.062; 257/E21.632

(57) ABSTRACT

A DMOS device and a method for fabricating the same are provided. A drift region and a well region are formed simultaneously to provide a DMOS device with the drift and well regions having the same depth. This DMOS device includes a high voltage transistor area and a low voltage transistor area, a drift diffused region formed in the high voltage transistor area, and a well region formed in the low voltage transistor area. A drift diffused region and a well region in the low voltage area are formed simultaneously to reduce the number of ion implantation processes, thereby simplifying the manufacturing process.

This application claims the benefit of Korean Patent Application No. 10-2006-0137345, filed on Dec. 29, 2006, which is hereby incorporated by reference as if fully set forth herein.

### BACKGROUND OF THE INVENTION

1. Field of the Invention

The present invention relates to a semiconductor device, and more particularly, to a Double-diffused Metal-Oxide-Semiconductor (DMOS) device and a method for fabricating the same.

2. Discussion of the Related Art

General power MOS Field Effect Transistors (MOSFETs) have higher input impedance than bipolar transistors.

Thus, MOSFETs provide a high power gain and require a very simple gate driving circuit. Since they are unipolar devices, MOSFETs have an advantage in that no time delay is caused by minority carrier storage and recombination when the devices are turned off.

Accordingly, the application of MOSFET devices to switching mode power supplies, lamp ballast, and motor drive circuits have gradually increased.

Generally, a Double-diffused MOSFET (DMOSFET) structure using the planar diffusion technology is widely used for such power MOSFETs. Lateral DMOS (LDMOS) transistors have been introduced in a technology that integrates them with CMOS transistors and bipolar transistors.

Conventional LDMOS devices are very suitable for use in VLSI processes by reason of their simple structure. However, LDMOS devices have been considered as having poorer characteristics than Vertical DMOS (VDMOS) devices. For this reason, LDMOS devices have not attracted much attention. Recently, REduced SURface Field (RESURF) LDMOS devices have been proven to have excellent ON-resistance (Rₛₚ).

A DMOS device has a structure in which a DMOS transistor and a CMOS transistor are integrated. The DMOS transistor forms therein a well region for the CMOS transistor and a high voltage well region separated from the well region to provide a high breakdown voltage of 20V or higher. The DMOS transistor also has a structure in which a drift diffused region is formed in the high voltage well region.

FIGS. 1 and 2 are sectional views illustrating a conventional DMOS device.

As shown in FIG. 1, low voltage transistor areas (LVN and LVP), middle voltage transistor areas (MVP and MVN), and high voltage diffused transistor areas (HVN and HVP) are defined in a semiconductor substrate of the conventional DMOS device and a deep n-well region 10 is also formed in the substrate.

A p-well region 12 and an n-well region 14 are formed by implanting an impurity into the semiconductor substrate above the deep n-well region 10. Then, an n-type ion implantation mask for n-type impurity implantation is formed on the substrate to form an n-type drift diffused region 16 with an n-type impurity implanted. The n-type ion implantation mask is then removed and a p-type ion implantation mask for p-type impurity implantation is formed on the substrate to form a p-type drift diffused region 18 with a p-type impurity implanted.

A trench isolation layer is then formed on the semiconductor substrate to separate the substrate surface into the transistor areas.

As shown in FIG. 2, a first well mask pattern is formed on the substrate in which the n-type drift diffused region 16 and the p-type drift diffused region 18 have been formed and an n-type impurity ion is then implanted to form an n-well 20. After the first well mask pattern is removed, a second well mask pattern is formed to form a p-well 22.

In the conventional DMOS fabricating method, the well region in the low voltage transistor area and the drift region for forming the diffused transistor are formed through separate processes. Thus, the conventional method has a problem in that it requires a number of photo processes and incurs a large loss in terms of the processing time and costs.

### SUMMARY OF THE INVENTION

Accordingly, the present invention is directed to a Double-diffused Metal-Oxide-Semiconductor (DMOS) device and a method for fabricating the same that substantially obviate one or more problems due to limitations and disadvantages of the related art.

An object of the present invention is to provide a DMOS device and a method for fabricating the same which reduce the number of photo processes when forming a DMOS device in which a well region and a drift region are formed in the same substrate, thereby simplifying the manufacturing process.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a drift region and a well region are formed simultaneously to provide a DMOS device with the drift and well regions having substantially the same depth. This DMOS device includes a high voltage transistor area and a low voltage transistor area, a drift diffused region formed in the high voltage transistor area, and a well region formed in the low voltage transistor area. The DMOS device is characterized in that the drift diffused region and the well region have substantially the same depth.

In another aspect of the present invention, a DMOS device fabricating method forms a drift region and a well region simultaneously. This method is characterized by defining a low voltage transistor area and a high voltage transistor area in a semiconductor substrate and forming a drift diffused region in the high voltage transistor area and a well region in the low voltage transistor area simultaneously.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1 and 2 are sectional views illustrating a conventional DMOS device and a conventional method for fabricating the same;

FIG. 3 is a sectional view of well regions of a DMOS device according to an embodiment of the present invention; and

FIGS. 4 to 6 are sectional views illustrating a method for fabricating a DMOS device according to an embodiment of the present invention.

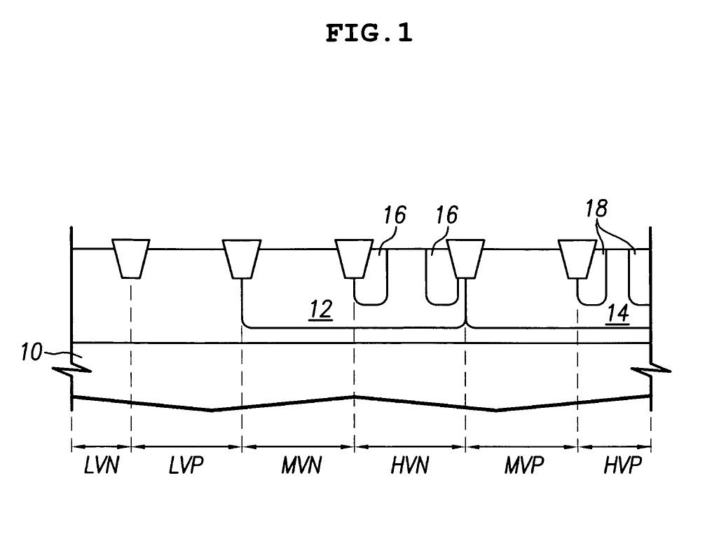

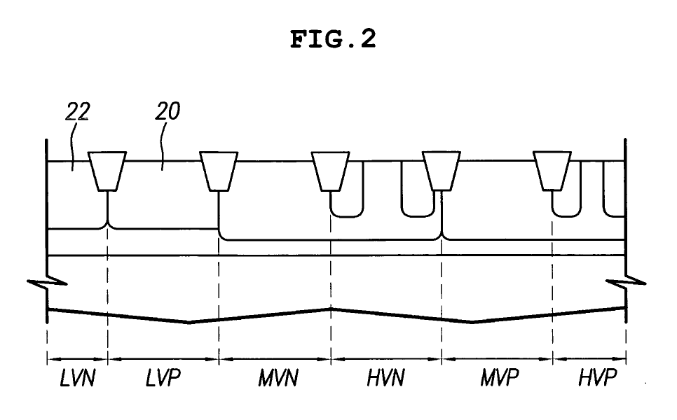

### DETAILED DESCRIPTION OF THE INVENTION

Reference will now be made in detail to the preferred embodiments of a DMOS device and a method for fabricating the same according to the present invention, examples of which are illustrated in the accompanying drawings. Wherever possible, the same reference numbers will be used throughout the drawings to refer to the same or like parts.

FIG. 3 is a sectional view of a well structure of a DMOS device according to an embodiment of the present invention.

As shown in FIG. 3, the DMOS device includes a deep n-well region 50 formed in a semiconductor substrate and a high voltage n-well region 52 and a high voltage p-well region 54 formed on the top of the deep n-well region 50.

N-type drift diffused regions 56 are formed in the high voltage p-well region 54 and p-type drift diffused regions 62 are formed in the high voltage n-well region 52.

In the DMOS device, a low voltage transistor area (LVN and LVP) and a high voltage transistor area (MVN, MVP, HVN, and HVP) are defined in the substrate. A isolation layer 70s is formed on the surface of the substrate to separate, from each other, middle voltage transistor regions (MVN and MVP) and high voltage diffused transistor regions (HVN and HVP) in the high voltage transistor area. The n-type drift diffused regions 56 and the p-type drift diffused regions 62 are formed in the n-type diffused transistor regions (HVN) and the p-type diffused transistor regions (HVP), respectively.

In the low voltage transistor area, an n-well 58 is formed to define a p-type low voltage transistor region (LVP) and a p-well 64 is formed to define an n-type low voltage transistor region (LVN).

In an example according to the present invention, the n-well 58 may be formed at the same depth as that of the n-type drift diffused region 56 and may also have the same doping concentration and the same profile as those of the n-type drift diffused region 56. In addition, the p-well 64 may be formed at the same depth as that of the p-type drift diffused region 62 and may also have the same doping concentration and the same profile as those of the p-type drift diffused region 62.

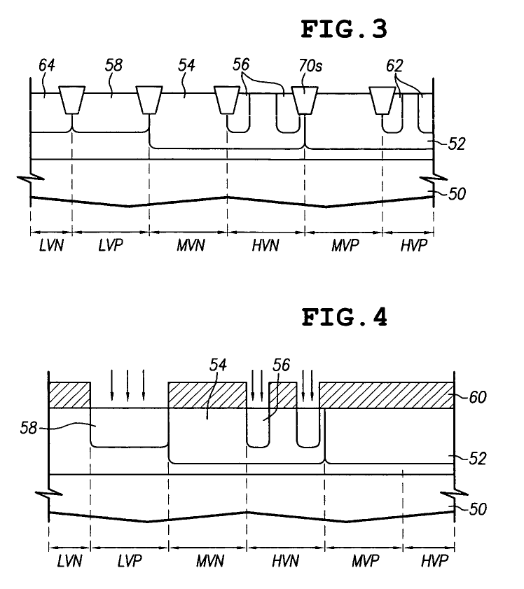

FIGS. 4 to 6 are drawings illustrating a method for fabricating a DMOS device according to an embodiment of the present invention.

As shown in FIG. 4, a low voltage transistor area (LVN and LVP) and a high voltage transistor area (MVN, MVP, HVN, and HVP) are separately defined in a semiconductor substrate and a deep n-well 50 is formed in the semiconductor substrate.

A high voltage n-well region 52 and a high voltage p-well region 54 are formed on the deep n-well 50. The high voltage n-well region 52 and the high voltage p-well region are formed in the high voltage transistor area defined in the semiconductor substrate.

A first mask pattern 60 is formed on the substrate with the high voltage n-well region 52 and the high voltage p-well region 54 formed. The first mask pattern 60 has openings through which the substrate in the high voltage p-well region 54 is partially exposed and the substrate in the low voltage transistor area is partially exposed.

An n-type impurity ion is implanted into the semiconductor substrate using the first mask pattern 60 as an ion implantation mask to form an n-type drift diffused region 56 in the high voltage p-well region 54. This implantation also forms an n-well 58 in the low voltage transistor area to define a p-type low voltage transistor region (LVP).

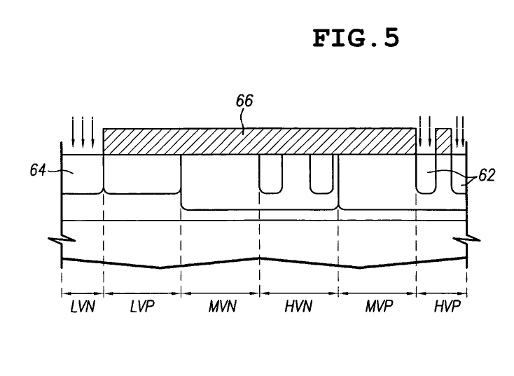

As shown in FIG. 5, the first mask pattern 60 is removed and a second mask pattern 66 is then formed on the substrate. For example, the second mask pattern 66 may be a reversed mask of the first mask pattern 60.

The second mask pattern 66 has openings through which the substrate in the high voltage n-well region 52 and the low voltage transistor area is partially exposed. A p-type impurity ion is implanted into the semiconductor substrate using the second mask pattern 66 as an ion implantation mask to form a p-type drift diffused region 62 in the high voltage n-well region 52. This implantation also forms a p-well 64 in the low voltage transistor area to define an n-type low voltage transistor region (LVN).

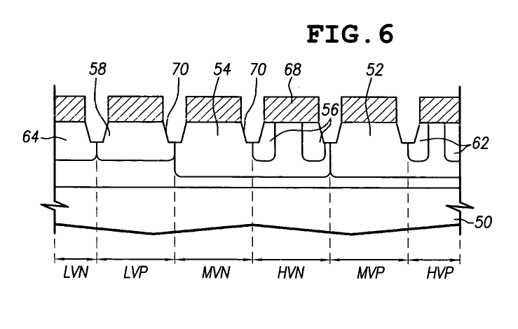

As shown in FIG. 6, the second mask pattern 66 is removed and a hard mask layer 68 for isolating devices is then formed on the substrate. A plurality of trench regions 70 is formed in the substrate using the hard mask layer 68 as an etching mask.

The trench regions 70 formed in the semiconductor substrate separate the substrate surface into the n-type low voltage transistor region (LVN) and the p-type low voltage transistor region (LVP) in the low voltage transistor area, the low voltage transistor area and the high voltage transistor area, and the middle voltage transistor regions (MVN and MVP) and the diffused transistor regions (HVN and HVP) in the high voltage transistor area.

Although not shown, the trench isolation layer 70s as shown in FIG. 3 may be formed by subsequently filling the trench regions 70 with an insulating layer and then performing planarizing and hard mask layer removing processes.

As is apparent from the above description, the present invention simultaneously forms a drift diffused region in the diffused transistor area and a well region in the low voltage transistor area. This reduces the number of processes for ion implantation and impurity diffusion and also reduces the number of photo processes for ion implantation, thereby simplifying the manufacturing process and reducing the manufacturing time.

In the present invention, although there is a need to find a doping concentration condition suitable for logic circuit transistor characteristics and DMOS transistor characteristics since the doping concentration of the well region is equal to that of the drift region, this need can be met by changing the structure of the DMOS transistor from a double diffused structure to a trench DMOS transistor structure

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A Double-diffused Metal-Oxide-Semiconductor (DMOS) device comprising:
a high voltage transistor area and a low voltage transistor area;
a drift diffused region formed in the high voltage transistor area; and
a well region formed in the low voltage transistor area,
wherein the drift diffused region and the well region have substantially the same depth.

2. The DMOS device according to claim 1, further comprising:
a high voltage well region formed in the high voltage transistor area,
wherein the drift diffused region is formed in the high voltage well region.

3. The DMOS device according to claim 1, further comprising:
a first conductive-type high voltage well region and a second conductive-type high voltage well region formed in the high voltage transistor area,
wherein a second conductive-type drift diffused region is formed in the first conductive-type high voltage well region and a first conductive-type drift diffused region is formed in the second conductive-type high voltage well region.

4. The DMOS device according to claim 3, wherein the well region formed in the low voltage transistor area includes a first conductive-type well region and a second conductive-type well region, and
wherein the first conductive-type well region and the first conductive-type drift diffused region have substantially the same depth and the second conductive-type well region and the second conductive-type drift diffused region have substantially the same depth.

5. A method for fabricating a DMOS device, the method comprising:
defining a low voltage transistor area and a high voltage transistor area in a semiconductor substrate; and
forming a drift diffused region in the high voltage transistor area and forming a well region in the low voltage transistor area simultaneously.

6. The method according to claim 5, further comprising:
forming a high voltage well region in the high voltage transistor area,
wherein the drift diffused region is formed in the high voltage well region.

7. The method according to claim 6, wherein the step of forming the drift diffused region and the well region includes:
forming a first mask pattern that exposes a predetermined area of the semiconductor substrate;
forming a first conductive-type well in the low voltage transistor area and forming a first conductive-type drift diffused region in the high voltage transistor area using the first mask pattern as an ion implantation mask;
forming a second mask pattern that exposes a predetermined area of the semiconductor substrate; and
forming a second conductive-type well in the low voltage transistor area and forming a second conductive-type drift diffused region in the high voltage transistor area using the second mask pattern as an ion implantation mask.

8. The method according to claim 7, further comprising:
forming a first conductive-type high voltage well region and a second conductive-type high voltage well region in the high voltage transistor area,
wherein the first conductive-type drift region is formed in the second conductive-type high voltage well region and the second conductive-type drift region is formed in the first conductive-type high voltage well region.

9. The method according to claim 8, further comprising:
forming a isolation layer on the semiconductor substrate to separate a surface of the substrate into a first conductive-type well region, a second conductive-type well region, a first conductive-type high voltage well region, and a second conductive-type high voltage well region and to define a middle voltage transistor region and a diffused transistor region in the substrate surface in the first conductive-type high voltage well region and the second conductive-type high voltage well region.

10. The method according to claim 9, wherein the diffused transistor region includes the drift diffused region.
